(19) United States
(12) Patent Application Publication
(10) Pub. No.: US 2023/0090976 A1
(43) Pub. Date: Mar. 23, 2023

(54) Bulk Acoustic Resonator and Filter

(71) Applicant: Wuhan MEMSonics Technologies Co.,Ltd., Wuhan (CN)

(72) Inventors: Chengliang SUN, Wuhan (CN); Xiyu GU, Wuhan (CN); Shishang GUO, Wuhan (CN); Chao GAO, Wuhan (CN); Yang ZOU, Wuhan (CN); Qinwen XU, Wuhan (CN)

(21) Appl. No.: 17/949,253

(22) Filed: Sep. 21, 2022

(30) Foreign Application Priority Data
Sep. 22, 2021 (CN) 202111105960.0

(51) Int. Cl. H03H 9/17; H03H 9/02; H03H 3/02; H03H 9/13; H03H 9/54

(52) U.S. Cl. CPC H03H 9/173; H03H 9/02015; H03H 3/02; H03H 9/132; H03H 9/54

(57) ABSTRACT

Provided are a bulk acoustic resonator and a filter. The bulk acoustic resonator includes a substrate having a cavity, and a bottom electrode, a piezoelectric layer and a top electrode that are sequentially arranged on the substrate, where an overlapping area of orthographic projections of the bottom electrode, the piezoelectric layer and the top electrode on the substrate forms a resonance area; and in the resonance area, an outline shape of the orthographic projection of each of the bottom electrode and the top electrode on the substrate is a closed figure formed by connecting M arcs end to end, and the closed figure is an axisymmetric figure, where M is an integer greater than or equal to 2, and the arcs include a concave arc that is concave toward a center of the resonance area and a convex arc that is convex away from the center of the resonance area.

### CROSS-REFERENCE TO RELATED APPLICATION

The disclosure claims the priority to Chinese Patent Application CN202111105960.0, filed on Sep. 22, 2021 and entitled “Bulk acoustic resonator and filter”, which is incorporated herein in its entirety by reference.

### TECHNICAL FIELD

The present disclosure relates to the technical field of resonators, and particularly relates to a bulk acoustic resonator and a filter.

### BACKGROUND

As rapid development of wireless communication technology leads to increasing congestion of wireless signals, new requirements such as integration, miniaturization, low power consumption, high performance and low cost have been imposed on filters working in a radio frequency area. With bulk acoustic waves as a signal transmission medium, a bulk acoustic wave (BAW) filter has higher power capacity than other filters, and has gradually become a research focus of a radio frequency filter for its high operating frequency, a high Q value, compatibility to a complementary metal oxide semiconductor (CMOS) technology, low loss and a low temperature coefficient.

Structurally, a bulk acoustic resonator is mainly composed of an electrode, a piezoelectric layer and an electrode, that is, a layer of piezoelectric material is sandwiched between two metal electrode layers. With a sinusoidal signal input between two electrodes, the bulk acoustic resonator is capable of converting an input electrical signal into mechanical resonance through an inverse piezoelectric effect, and then converting the mechanical resonance into an electrical signal for output through a piezoelectric effect. In the case of an existing bulk acoustic resonator, propagation in a piezoelectric layer will cause deformation and oscillation of an upper electrode and a lower electrode in a horizontal direction of the piezoelectric layer, outward propagation, reflection and even secondary acoustic waves or standing waves, thereby further affecting a quality factor of the bulk acoustic resonator.

### SUMMARY

An objective of the present invention is to provide a bulk acoustic resonator and a filter, which may reduce acoustic degeneracy, thus reducing clutter resonance peaks and pseudo modes, so as to obtain a pure dominant mode having a large electromechanical coupling coefficient.

Embodiments of the present disclosure are implemented as follows:

An aspect of the present disclosure provides a bulk acoustic resonator. The bulk acoustic resonator includes a substrate having a cavity, and a bottom electrode, a piezoelectric layer and a top electrode that are sequentially arranged on the substrate. An overlapping area of orthographic projections of the bottom electrode, the piezoelectric layer and the top electrode on the substrate forms a resonance area. In the resonance area, an outline shape of the orthographic projection of each of the bottom electrode and the top electrode on the substrate is a closed figure formed by connecting M arcs end to end, and the closed figure is an axisymmetric figure, where M is an integer greater than or equal to 2, and the arcs include a concave arc that is concave toward a center of the resonance area and a convex arc that is convex away from the center of the resonance area. The bulk acoustic resonator may reduce acoustic degeneracy, thus reducing clutter resonance peaks and pseudo modes, so as to obtain a pure dominant mode having a large electromechanical coupling coefficient.

In an embodiment, the concave arc and the convex arc are alternatively arranged.

In an embodiment, the arcs include a first arc and a second arc that are sequentially connected end to end, the first arc is a convex arc, and the second arc is a concave arc.

In an embodiment, the arcs include a first arc, a second arc, a third arc and a fourth arc that are sequentially connected end to end, the first arc and the third arc are convex arcs and are symmetrically arranged with respect to a first direction, and the second arc and the fourth arc are concave arcs and are symmetrically arranged with respect to a second direction. The first direction is perpendicular to the second direction.

In an embodiment, the arcs include a first arc, a second arc, a third arc, a fourth arc, a fifth arc, a sixth arc, a seventh arc and an eighth arc that are sequentially connected end to end. The first arc, the third arc, the fifth arc and the seventh arc are convex arcs, and the second arc, the fourth arc, the sixth arc and the eighth arc are concave arcs.

In an embodiment, the piezoelectric layer is made of any one of aluminum nitride, lithium niobate, lithium tantalate, lead zirconate titanate and scandium-doped aluminum nitride.

In an embodiment, the bottom electrode is made of any one of molybdenum, aluminum, platinum, silver, tungsten and gold.

In an embodiment, the top electrode is made of any one of molybdenum, aluminum, platinum, silver, tungsten and gold.

In an embodiment, in the resonance area, an outline shape of the orthographic projection of the piezoelectric layer on the substrate is a closed figure formed by connecting M arcs end to end, and the closed figure is an axisymmetric figure, where M is an integer greater than or equal to 2, and the arcs include a concave arc that is concave toward the center of the resonance area and a convex arc that is convex away from the center of the resonance area.

Another aspect of the present disclosure provides a filter. The filter includes the above-described bulk acoustic resonator. The bulk acoustic resonator includes a substrate having a cavity, and a bottom electrode, a piezoelectric layer and a top electrode that are sequentially arranged on the substrate. An overlapping area of orthographic projections of the bottom electrode, the piezoelectric layer and the top electrode on the substrate forms a resonance area.

In the resonance area, an outline shape of the orthographic projection of each of the bottom electrode and the top electrode on the substrate is a closed figure formed by connecting M arcs end to end, and the closed figure is an axisymmetric figure, where M is an integer greater than or equal to 2, and the arcs include a concave arc that is concave toward a center of the resonance area and a convex arc that is convex away from the center of the resonance area.

In an embodiment, the concave arc and the convex arc are alternatively arranged.

Further disclosed is a method for manufacturing a bulk acoustic resonator. The method includes providing a substrate having a cavity, sequentially forming a bottom electrode, a piezoelectric layer and a top electrode on the substrate, and forming a resonance area by an overlapping area of orthographic projections of the bottom electrode, the piezoelectric layer and the top electrode on the substrate.

In the resonance area, an outline shape of the orthographic projection of each of the bottom electrode and the top electrode on the substrate is a closed figure formed by connecting M arcs end to end, and the closed figure is an axisymmetric figure, where M is an integer greater than or equal to 2, and the arcs include a concave arc that is concave toward a center of the resonance area and a convex arc that is convex away from the center of the resonance area.

In an embodiment, the bottom electrode is etched into a closed figure having an outline shape formed by connecting M arcs end to end through photolithography and an ion etching technology, and the closed figure is an axisymmetric figure.

In an embodiment, the piezoelectric layer is made of any one of aluminum nitride, lithium niobate, lithium tantalate, lead zirconate titanate and scandium-doped aluminum nitride.

In an embodiment, shapes of the orthographic projections of the top electrode and the bottom electrode on the substrate coincide, or an area of the orthographic projection of the top electrode on the substrate is greater than that of the orthographic projection of the bottom electrode on the substrate, or an area of the orthographic projection of the top electrode on the substrate is smaller than that of the orthographic projection of the bottom electrode on the substrate.

In an embodiment, the substrate is etched to form a first cavity, and an outline shape of an orthographic projection of the first cavity on the substrate is the same as that of the orthographic projection of the top electrode on the substrate.

In an embodiment, the substrate is etched to form a second cavity, a sacrificial layer is deposited in the second cavity, a release hole is etched through photolithography and an ion etching technology, and etching gas or liquid is introduced to remove the sacrificial layer.

In an embodiment, a seed layer grows on the sacrificial layer, further the piezoelectric layer grows on the seed layer, and the seed layer provides a lattice matching interface required for growth of the piezoelectric layer.

In an embodiment, shapes of the orthographic projections of the top electrode and the bottom electrode on the substrate coincide, or an area of the orthographic projection of the top electrode on the substrate is greater than that of the orthographic projection of the bottom electrode on the substrate, or an area of the orthographic projection of the top electrode on the substrate is smaller than that of the orthographic projection of the bottom electrode on the substrate.

In an embodiment, an outline shape of an orthographic projection of the second cavity on the substrate is the same as that of the orthographic projection of the top electrode on the substrate.

The present disclosure has the beneficial effects as follows:

The bulk acoustic resonator provided by the disclosure includes the substrate having the cavity, and the bottom electrode, the piezoelectric layer and the top electrode that are sequentially arranged on the substrate, where the overlapping area of the orthographic projections of the bottom electrode, the piezoelectric layer and the top electrode on the substrate forms the resonance area; and in the resonance area, the outline shape of the orthographic projection of each of the bottom electrode and the top electrode on the substrate is the closed figure formed by connecting M arcs end to end, and the closed figure is an axisymmetric figure, where M is an integer greater than or equal to 2, and the arcs include a concave arc that is concave toward the center of the resonance area and a convex arc that is convex away from the center of the resonance area. According to the disclosure, the top electrode and the bottom electrode are arranged to have closed and symmetrical figures delimited by the convex arc and the concave arc, such that a probability of repeated appearance of a same reflection point may be effectively reduced, unnecessary acoustic degeneracy generated in a horizontal plane may be reduced, unnecessary acoustic vibration modes may cancel each other out, and degeneracy of unnecessary absorption spectrum peaks is greatly reduced. In this way, clutter resonance peaks and pseudo modes are reduced, and then a pure dominant mode having a large electromechanical coupling coefficient is obtained. The bulk acoustic resonator provided by the disclosure may effectively improve a quality factor thereof.

### BRIEF DESCRIPTION OF THE DRAWINGS

To describe technical solutions in embodiments of the present disclosure more clearly, the accompanying drawings required in the embodiments will be briefly introduced below. It should be understood that the following accompanying drawings show merely some embodiments of the present disclosure, which are not regarded as a limitation on the scope, and those of ordinary skill in the art may still derive other related accompanying drawings from these accompanying drawings without creative efforts.

FIG. 1 is a structural schematic diagram of a bulk acoustic resonator provided by an embodiment of the present invention;

FIG. 2 is a first schematic diagram of an outline shape of an orthographic projection of each of a bottom electrode and a top electrode on a substrate provided by an embodiment of the present invention;

FIG. 3 is a second schematic diagram of an outline shape of an orthographic projection of each of a bottom electrode and a top electrode on a substrate provided by an embodiment of the present invention;

FIG. 4 is a third schematic diagram of an outline shape of an orthographic projection of each of a bottom electrode and a top electrode on a substrate provided by an embodiment of the present invention;

FIG. 5 is an impedance effect diagram corresponding to FIG. 4; and

FIG. 6 is a schematic diagram of a filter provided by an embodiment of the present invention.

Reference signs: 10-substrate; 11-cavity; 20-bottom electrode; 30-piezoelectric layer; 40-top electrode; 50-resonance area; a-first direction; and b-second direction.

### DETAILED DESCRIPTION OF THE EMBODIMENTS

The embodiments described below indicate information required for those skilled in the art to implement the embodiments, and show an optimal mode of implementing the embodiments. After reading the following description with reference to the accompanying drawings, those skilled in the art will understand concepts of the present disclosure, and will recognize applications of the concepts not specifically proposed herein. It should be understood that the concepts and applications fall within the scope of the present disclosure and the appended claims.

It should be understood that the terms such as “first” and “second” may be used to describe various elements herein, but the elements should not be limited by the terms. The terms are merely used to distinguish an element and another element. For example, without departing from the scope of the present disclosure, a first element may also be called a second element, and similarly, a second element may also be called a first element. As used herein, the term “and/or” includes any or all combinations of one or more in associated items that are listed.

It should be understood that when an element (for example, a layer, an area, or a substrate 10) is described as “being on another element” or “extending to another element”, the element may be directly on another element or directly extend to another element, or intervening elements may also be exist. On the contrary, when an element is described as “being directly on another element” or “directly extending to another element”, no intervening element may exist. Also, it should be understood that when an element (for example, a layer, an area, or a substrate 10) is described as “being above another element” or “extending above another element”, the element may be directly above another element or directly extend above another element, or intervening elements may also be exist. On the contrary, when an element is described as “being directly above another element” or “directly extending above another element”, no intervening element exists. It should be further understood that when an element is described as being “connected” or “coupled” to another element, the element may be directly connected or coupled to another element, or intervening elements may exist. On the contrary, when an element is described as being “directly connected” or “directly coupled” to another element, no intervening element exists.

The related terms such as “below”, “above”, “on”, “under”, “horizontal” or “perpendicular” may be used to describe a relation between an element, a layer or an area and another element, layer or area herein, as shown in the figures. It should be understood that the terms and those discussed above are intended to cover different orientations of a device other than orientations depicted in the figures.

The terms used herein are merely used to describe specific embodiments and are not intended to limit the present disclosure. As used herein, the singular forms “a”, “an”, and “the” are intended to include plural forms as well, unless otherwise explicitly indicated in the context. It should be further understood that the term “comprise/include” used herein indicates presence of the described features, integers, steps, operations, elements and/or components, but does not exclude the presence or addition of one or more other features, integers, steps, operations, elements, components and/or groups thereof.

Unless otherwise defined, all terms (including technical and scientific terms) used herein have the same meanings as commonly understood by those of ordinary skill in the art to which the present disclosure belongs. It should be further understood that the terms used herein should be explained to have meanings consistent with the meanings in the description and related art and cannot be explained with ideal or excessively formal meanings, unless expressly so defined herein.

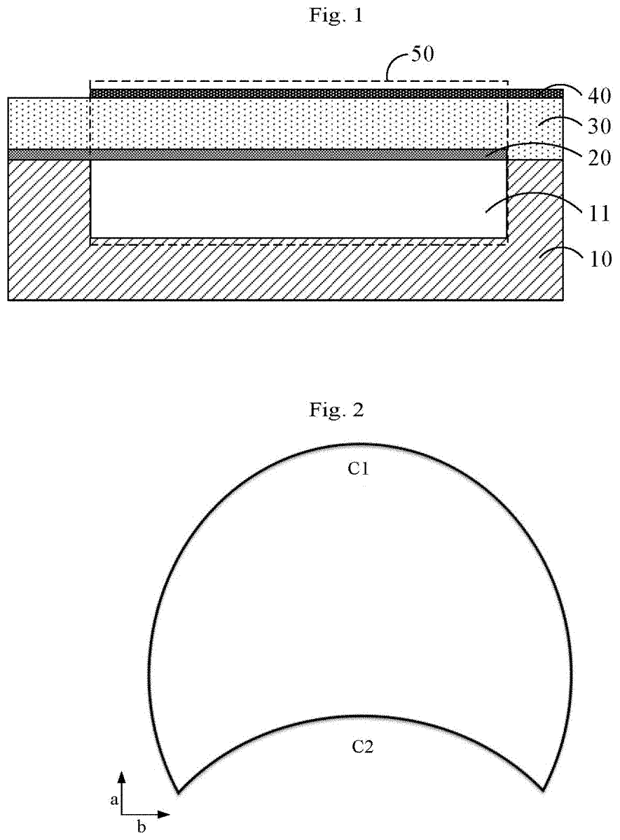

With reference to FIG. 1, the embodiment provides a bulk acoustic resonator. The bulk acoustic resonator includes a substrate 10 having a cavity 11, and a bottom electrode 20, a piezoelectric layer 30 and a top electrode 40 that are sequentially arranged on the substrate 10. An overlapping area of orthographic projections of the bottom electrode 20, the piezoelectric layer 30 and the top electrode 40 on the substrate 10 forms a resonance area 50. In the resonance area 50, an outline shape of the orthographic projection of each of the bottom electrode 20 and the top electrode 40 on the substrate 10 is a closed figure formed by connecting M arcs end to end, and the closed figure is an axisymmetric figure, where M is an integer greater than or equal to 2, and the arcs include a concave arc that is concave toward a center of the resonance area 50 and a convex arc that is convex away from the center of the resonance area 50. The bulk acoustic resonator may reduce acoustic degeneracy, thus reducing clutter resonance peaks and pseudo modes, so as to obtain a pure dominant mode having a large electromechanical coupling coefficient.

The piezoelectric layer 30 is located between the top electrode 40 and the bottom electrode 20. When a voltage is applied between the top electrode 40 and the bottom electrode 20, the bulk acoustic resonator may generate an electric field in an area of the piezoelectric layer 30 corresponding to the top electrode 40 and the bottom electrode 20. According to an inverse piezoelectric effect, electric energy generated in the piezoelectric layer 30 tends to be converted into mechanical energy in a form of acoustic waves, and the acoustic waves are propagated in a direction of the electric field, that is, in a vertical direction corresponding to FIG. 1.

In the embodiment, the piezoelectric layer 30 is made of any one of aluminum nitride, lithium niobate, lithium tantalate and lead zirconate titanate. In addition, in the embodiment, the piezoelectric layer 30 may also use a piezoelectric material doped with rare earth elements, such as scandium-doped aluminum nitride. In the embodiment, the bottom electrode 20 and the top electrode 40 may both made of any one of molybdenum, aluminum, platinum, silver, tungsten and gold.

As shown in FIG. 1, the resonance area 50 is the overlapping area of the orthographic projections of the bottom electrode 20, the piezoelectric layer 30 and the top electrode 40 on the substrate 10. The resonance area 50 is a working area of a resonator. The resonance area 50 is well known to those skilled in the art, which will not be repeated in the disclosure.

As shown in FIGS. 2-4, in the resonance area 50, the outline shape of the orthographic projection of each of the bottom electrode 20 and the top electrode 40 on the substrate 10 is formed by connecting M arcs end to end, and the outline shape is a closed figure that is axisymmetric. M is an integer greater than or equal to 2. In short, the orthographic projections of the bottom electrode 20 and the top electrode 40 on the substrate 10 are closed and symmetrical figures composed of all arcs.

It should be noted that when a voltage is applied between the top electrode 40 and the bottom electrode 20, due to the inverse piezoelectric effect of the piezoelectric material of the piezoelectric layer 30, mechanical stress generated by the coupling of different piezoelectric stress coefficients may excite acoustic waves propagated longitudinally in the piezoelectric layer 30, thus corresponding to different vibration modes and harmonic sequences of absorption bands in a filter absorption spectrum. The frequency bands tend to have a center frequency of f=v×N/(2h), v being a sound speed of a propagation mode, h being a thickness of mode propagation (which is a thickness of the piezoelectric layer 30 corresponding to FIG. 1), and N being the number of reflection points having a same frequency. When the number of reflection points having the same frequency is greater (that is, an N value is greater), acoustic degeneracy may be more likely to occur, further a resonant mode may be formed, and an amplitude of a resonance peak in a corresponding absorption spectrum may be higher. The reflection points of the acoustic waves are mainly generated at density abrupt-change positions of surfaces and edges of the top electrode 40 and the bottom electrode 20 and at an edge of the cavity 11. In addition, due to the inverse piezoelectric effect, acoustic waves (that is, transverse waves) may also be generated in a horizontal direction. When the number of reflection points having the same frequency increases, the clutter resonance peak may also be formed, which may affect a device to obtain a pure resonance peak mode. According to the disclosure, a shape of each of the bottom electrode 20 and the top electrode 40 in the resonance area 50 is designed into a closed and symmetrical figure formed by connecting M arcs, and the arcs include a concave arc and a convex arc. In this way, a reflection path of the acoustic waves may be effectively increased, and then a probability that the acoustic waves reflected from the reflection point are reflected back to the reflection point at an edge of an electrode may be effectively reduced (as shown in FIG. 4, a dotted line is a propagation path of acoustic waves generated on the horizontal plane, from point A to point B, a plurality of reflection points are passed, and the shapes of the top electrode 40 and the bottom electrode 20 provided by the disclosure may effectively reduce a probability of repeated appearance of a same reflection point, such that unnecessary acoustic degeneracy generated on the horizontal plane may be reduced). Therefore, an N value may be effectively reduced, degeneracy of unnecessary absorption spectrum peaks is greatly reduced, and then the clutter resonance peaks are reduced.

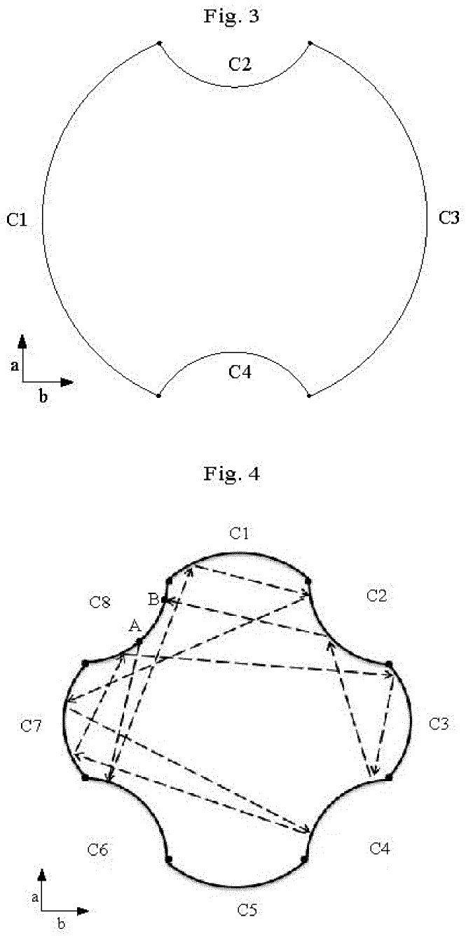

It should be further noted that in the embodiment, the closed figure is an axisymmetric figure. Herein, the term “symmetry” does not indicate absolute symmetry in a mathematical sense, but may also include a range of approximate symmetry. That is, the description that the closed figure is an axisymmetric figure merely indicates that the closed figure is symmetrically arranged compared with the situation that the closed figure is an asymmetric figure. With FIG. 3 as an example, in FIG. 3, a first arc C1 and a third arc C3 are approximately symmetrically arranged left and right with respect to a first direction a, and a second arc C2 and a fourth arc C4 are approximately symmetrically arranged up and down with respect to a second direction b.

To sum up, the bulk acoustic resonator provided by the disclosure includes the substrate 10 having the cavity 11, and the bottom electrode 20, the piezoelectric layer 30 and the top electrode 40 that are sequentially arranged on the substrate 10. The overlapping area of the orthographic projections of the bottom electrode 20, the piezoelectric layer 30 and the top electrode 40 on the substrate 10 forms the resonance area 50. In the resonance area 50, the outline shape of the orthographic projection of each of the bottom electrode 20 and the top electrode 40 on the substrate 10 is the closed figure formed by connecting M arcs end to end, and the closed figure is an axisymmetric figure, where M is an integer greater than or equal to 2, and the arcs include a concave arc that is concave toward the center of the resonance area 50 and a convex arc that is convex away from the center of the resonance area 50. According to the disclosure, the top electrode 40 and the bottom electrode 20 are arranged to have the closed and symmetrical figures delimited by the concave arc and the convex arc, such that the reflection path of the acoustic waves may be effectively increased, then the probability of repeated appearance of the same reflection point may be reduced, the unnecessary acoustic degeneracy generated in the horizontal plane may be reduced, the unnecessary acoustic vibration modes may cancel each other out, and the degeneracy of the unnecessary absorption spectrum peaks is greatly reduced. In this way, the clutter resonance peaks and pseudo modes are reduced, and then the pure dominant mode having the large electromechanical coupling coefficient is obtained. The bulk acoustic resonator provided by the disclosure may effectively improve a quality factor thereof.

With reference to FIGS. 2-4, optionally, in the embodiment, the arcs include a concave arc that is concave toward the center of the resonance area 50 and a convex arc that is convex away from the center of the resonance area 50. A curvature radius of the arcs is not limited by the disclosure, and may be determined by those skilled in the art according to an actual situation, as long as the arcs are smooth. In addition, in the embodiment, the number of arcs is greater than or equal to 2, and the specific number of arcs and corresponding lengths of the arcs are not limited by the disclosure, and may be selected by those skilled in the art according to a size of the resonance area 50. For a resonator having a resonance area on an air cavity, when closed figures of a bottom electrode and a top electrode are axisymmetric figures, membrane stress generated after etching a base material below a membrane when the air cavity is to be formed may be effectively balanced. In this way, warpage and unevenness of the membrane in a resonance area above the air cavity are reduced, average quality of the membrane is improved, and performance of the resonator is further enhanced, as shown in FIG. 6.

It should be noted that with FIG. 4 as an example, an arc C1, an arc C3, an arc C5 and an arc C7 are all convex arcs; and an arc C2, an arc C4, an arc C6 and an arc C8 are all concave arcs. Apexes of the concave arcs are close to the center of the resonance area 50, and apexes of the convex arcs are far away from the center of the resonance area 50, which may be clearly known by those skilled in the art according to the above description in conjunction with FIG. 4, thus being not repeated in the disclosure.

In an embodiment, with reference to FIGS. 2-4, optionally, M is an integer greater than or equal to 2, and a concave arc and a convex arc are alternatively arranged. In short, the outline shapes of the orthographic projections of the top electrode 40 and the bottom electrode 20 on the substrate 10 are closed figures composed of all arcs, and the concave arc and the convex arc are alternatively arranged.

Exemplarily, in a first case, the outline shapes of the orthographic projections of the top electrode 40 and the bottom electrode 20 on the substrate 10 may also be as shown in FIG. 2. In this case, the arcs include a first arc C1 and a second arc C2 that are sequentially connected end to end, the first arc C1 is a convex arc, and the second arc C2 is a concave arc. As shown in FIG. 2, in this case, the closed figure is similar to a crescent shape.

Exemplarily, in a second case, the outline shapes of the orthographic projections of the top electrode 40 and the bottom electrode 20 on the substrate 10 may also be as shown in FIG. 3. In this case, the arcs include a first arc C1, a second arc C2, a third arc C3 and a fourth arc C4 that are sequentially connected end to end, the first arc C1 and the third arc C3 are convex arcs and are symmetrically arranged with respect to a first direction a, and the second arc C2 and the fourth arc C4 are concave arcs and are symmetrically arranged with respect to a second direction b. The first direction a is perpendicular to the second direction b.

Exemplarily, in a third case, the outline shapes of the orthographic projections of the top electrode 40 and the bottom electrode 20 on the substrate 10 may also be as shown in FIG. 4. In this case, the arcs include a first arc C1, a second arc C2, a third arc C3, a fourth arc C4, a fifth arc C5, a sixth arc C6, a seventh arc C7 and an eighth arc C8 that are sequentially connected end to end. The first arc C1 and the third arc C3 are convex arcs and are symmetrically arranged with respect to a second direction b, the second arc C2 and the eighth arc C8 are concave arcs and are symmetrically arranged with respect to a first direction a, the third arc C3 and the seventh arc C7 are convex arcs and are symmetrically arranged with respect to the first direction a, and the fourth arc C4 and the sixth arc C6 are concave arcs and are symmetrically arranged with respect to the first direction a. The first direction a is perpendicular to the second direction b.

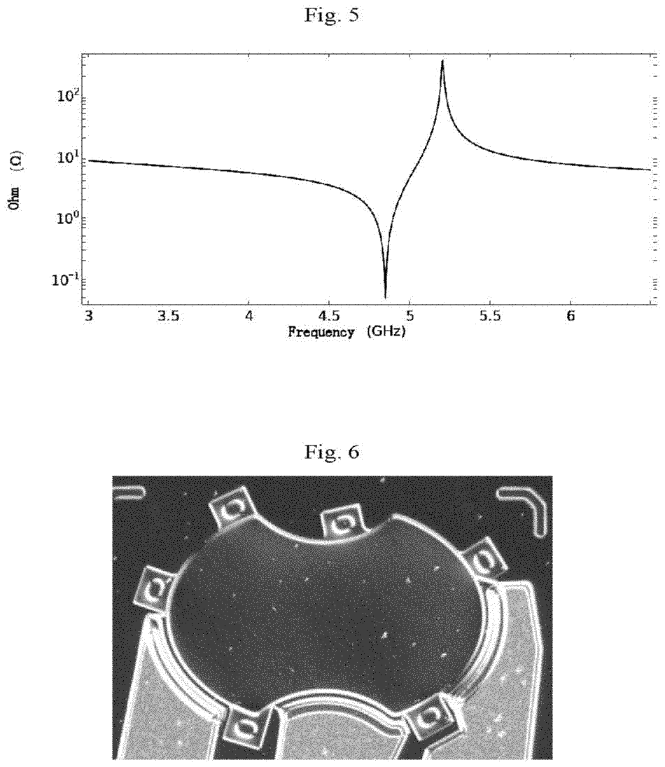

In this case, with reference to FIG. 5, FIG. 5 is an impedance effect diagram of FIG. 4. In the disclosure, the shapes of the top electrode 40 and the bottom electrode 20 are improved as described above, smoothness of a response curve obtained is desirable, and peaks and recesses of impedance glitch compensate for each other well, such that smoothness of a filter response curve may be significantly improved.

In addition to designing the outline shapes of the orthographic projections of the top electrode 40 and the bottom electrode 20 on the substrate 10 into a form of all arcs in the disclosure, optionally, in the resonance area 50, an outline shape of the orthographic projection of the piezoelectric layer 30 on the substrate 10 may also be a closed figure formed by connecting M arcs end to end, and the closed figure is an axisymmetric figure, where M is an integer greater than or equal to 2, and the arcs include a concave arc that is concave toward the center of the resonance area 50 and a convex arc that is convex away from the center of the resonance area 50.

That is, the outline shape of the piezoelectric layer 30 in the resonance area 50 may be similar to the outline shapes of the top electrode 40 and the bottom electrode 20 in the resonance area 50. In this way, the acoustic waves in the piezoelectric layer 30 may be further fully reflected, such that unnecessary acoustic vibration modes cancel each other out, and a pure dominant mode having a large electromechanical coupling coefficient may be obtained.

Another aspect of the present disclosure provides a method for manufacturing a resonator. Firstly, a seed layer material, such as aluminum oxynitride, tungsten nitride, titanium tungsten nitride, silicon oxide or silicon nitride, grew on a substrate, so as to play a supporting role and improve a desirable lattice matching interface required for subsequent high-quality membrane growth. Then, a bottom electrode layer material, such as molybdenum, aluminum, neodymium, copper or silver, grew through physical vapor deposition (PVD) technology. A bottom electrode was etched into a closed figure having an outline shape formed by connecting M arcs end to end through photolithography and an ion etching technology, and the closed figure was an axisymmetric figure; and in addition, compared with other shapes, the shape may reduce the number of outline intersection angles, and reduce harsh requirements for photolithography and an ion etching technology. Another layer of piezoelectric material, such as aluminum nitride, scandium-doped aluminum nitride, zinc oxide or lead zirconate titanate (PZT), grew. The piezoelectric layer was etched through photolithography and an ion etching technology, so as to expose a connecting potential position of the bottom electrode. Then, a top electrode layer material, such as molybdenum, aluminum, neodymium, copper or silver, grew through the PVD technology. PVD is physical vapor deposition. Electrodes and the piezoelectric material may grow through magnetron sputtering, and then a top electrode was etched into a same outline shape as the bottom electrode through photolithography and an ion etching technology. Orthographic projections of the top electrode and the bottom electrode coincided, or a projection of the top electrode was greater or smaller than that of the bottom electrode by 5 microns. Then, a base material was etched from a back of a base, so as to form an air cavity having a same outline shape as the top electrode, and an orthographic projection and the orthographic projections of the top electrode and the bottom electrode coincided, or a projection of the air cavity was greater or smaller than that of the bottom electrode by 10 microns.

Another aspect of the present disclosure provides a method for manufacturing a resonator. Firstly, a base material was etched to form an air cavity having a same outline shape as a top electrode, and an orthographic projection and orthographic projections of the top electrode and a bottom electrode coincided, or a projection of the air cavity was greater or smaller than that of the bottom electrode by 10 microns. Then, a sacrificial layer was deposited in the air cavity. A seed layer material, such as aluminum oxynitride, tungsten nitride, titanium tungsten nitride, silicon oxide or silicon nitride, grew on the sacrificial layer, so as to play a supporting role and improve a desirable lattice matching interface required for subsequent high-quality membrane growth. Then, a bottom electrode layer material, such as molybdenum, aluminum, neodymium, copper or silver, grew through the PVD technology. The bottom electrode was etched into a closed figure having an outline shape formed by connecting M arcs end to end through photolithography and an ion etching technology, and the closed figure was an axisymmetric figure; and in addition, compared with other shapes, the shape may reduce the number of outline intersection angles, and reduce harsh requirements for photolithography and an ion etching technology. Another layer of piezoelectric material, such as aluminum nitride, scandium-doped aluminum nitride, zinc oxide or PZT, grew. The piezoelectric layer was etched through photolithography and an ion etching technology, so as to expose a connecting potential position of the bottom electrode. Then, a top electrode layer material, such as molybdenum, aluminum, neodymium, copper or silver, grew through the PVD technology. The top electrode was etched into a same outline shape as the bottom electrode through photolithography and an ion etching technology. The orthographic projections of the top electrode and the bottom electrode coincided, or a projection of the top electrode was greater or smaller than that of the bottom electrode by 5 microns. Then, a release hole was etched through photolithography and an ion etching technology, and etching gas or liquid was introduced to remove a sacrificial layer material. In this case, due to symmetry of axisymmetric figures, stress was balanced, and warpage of a membrane above the air cavity was effectively alleviated.

Another aspect of the present disclosure provides a filter. The filter includes the above-described bulk acoustic resonator. The bulk acoustic resonator includes a substrate having a cavity, and a bottom electrode, a piezoelectric layer and a top electrode that are sequentially arranged on the substrate. An overlapping area of orthographic projections of the bottom electrode, the piezoelectric layer and the top electrode on the substrate forms a resonance area.

In the resonance area, an outline shape of the orthographic projection of each of the bottom electrode and the top electrode on the substrate is a closed figure formed by connecting M arcs end to end, and the closed figure is an axisymmetric figure, where M is an integer greater than or equal to 2, and the arcs include a concave arc that is concave toward a center of the resonance area and a convex arc that is convex away from the center of the resonance area. A specific structure and beneficial effects of the bulk acoustic resonator are described and illustrated in detail in the above description, which will not be repeated herein.

The concave arc and the convex arc are alternatively arranged.

Further disclosed is a method for manufacturing a bulk acoustic resonator. The method includes providing a substrate having a cavity, sequentially forming a bottom electrode, a piezoelectric layer and a top electrode on the substrate, and forming a resonance area by an overlapping area of orthographic projections of the bottom electrode, the piezoelectric layer and the top electrode on the substrate.

In the resonance area, an outline shape of the orthographic projection of each of the bottom electrode and the top electrode on the substrate is a closed figure formed by connecting M arcs end to end, and the closed figure is an axisymmetric figure, where M is an integer greater than or equal to 2, and the arcs include a concave arc that is concave toward a center of the resonance area and a convex arc that is convex away from the center of the resonance area.

The bottom electrode is etched into a closed figure having an outline shape formed by connecting M arcs end to end through photolithography and an ion etching technology, and the closed figure is an axisymmetric figure.

The top electrode is etched into a closed figure having an outline shape formed by connecting M arcs end to end through photolithography and an ion etching technology, and the closed figure is an axisymmetric figure.

Shapes of the orthographic projections of the top electrode and the bottom electrode on the substrate coincide, or an area of the orthographic projection of the top electrode on the substrate is greater than that of the orthographic projection of the bottom electrode on the substrate, or an area of the orthographic projection of the top electrode on the substrate is smaller than that of the orthographic projection of the bottom electrode on the substrate. According to product requirements, when an area of the top electrode is greater than that of the bottom electrode, in-band loss may be reduced, but a bandwidth decreases, and when an area of the top electrode is smaller than that of the bottom electrode, in-band loss may be increased, but a bandwidth increases.

The substrate is etched to form a first cavity, and an outline shape of an orthographic projection of the first cavity on the substrate is the same as that of the orthographic projection of the top electrode on the substrate. An effective air cavity having a same shape is formed, so as to facilitate reflection of acoustic waves.

The substrate is etched to form a second cavity, a sacrificial layer is deposited in the second cavity, a release hole is etched through photolithography and an ion etching technology, and etching gas or liquid is introduced to remove the sacrificial layer. The etching gas is vapor hydrogen fluoride (VHF); and the etching liquid is buffered oxide etch (BOE), and hydrogen fluoride (HF).

A seed layer grows on the sacrificial layer, further the piezoelectric layer grows on the seed layer, and the seed layer provides a lattice matching interface required for growth of the piezoelectric layer. After etching of the bottom electrode is completed, most other areas of the substrate are still seed layers, and the piezoelectric layer grows on the seed layers. When the seed layers are made of a same or similar piezoelectric material, desirable lattice interface and growth environment are formed, and a growing piezoelectric layer may have better crystal quality and piezoelectric performance.

Shapes of the orthographic projections of the top electrode and the bottom electrode on the substrate coincide, or an area of the orthographic projection of the top electrode on the substrate is greater than that of the orthographic projection of the bottom electrode on the substrate, or an area of the orthographic projection of the top electrode on the substrate is smaller than that of the orthographic projection of the bottom electrode on the substrate.

An outline shape of an orthographic projection of the second cavity on the substrate is the same as that of the orthographic projection of the top electrode on the substrate.

The filter may be constructed by two or more bulk acoustic resonators. Construction methods of resonators and filters are well known to those skilled in the art, which will not be repeated in the disclosure. In addition, it should be noted that when the number of resonators is greater than 2, outline shapes of a top electrode 40 and a bottom electrode 20 of each resonator may be the same as or different from outline shapes of top electrodes 40 and bottom electrodes 20 of other resonators, which are not limited in the disclosure and may be determined by those skilled in the art according to actual requirements.

The above description is merely optional embodiments of the present disclosure and is not intended to limit the present disclosure, and various changes and modifications of the present disclosure may be made by those skilled in the art. Any modifications, equivalent substitutions, improvements, etc. within the spirit and principles of the present disclosure are intended to fall within the scope of protection of the present disclosure.

It should also be noted that various specific technical features described in the above-described specific embodiments may be combined in any suitable manner, without contradiction. In order to avoid unnecessary repetition, various possible combinations will not be described separately in the present disclosure.

What is claimed is:

1. A bulk acoustic resonator, comprising a substrate having a cavity, and a bottom electrode, a piezoelectric layer and a top electrode that are sequentially arranged on the substrate, wherein an overlapping area of orthographic projections of the bottom electrode, the piezoelectric layer and the top electrode on the substrate forms a resonance area; and
in the resonance area, an outline shape of the orthographic projection of each of the bottom electrode and the top electrode on the substrate is a closed figure formed by connecting M arcs end to end, and the closed figure is an axisymmetric figure, wherein M is an integer greater than or equal to 2, and the arcs comprise a concave arc that is concave toward a center of the resonance area and a convex arc that is convex away from the center of the resonance area.

2. The bulk acoustic resonator according to claim 1, wherein the concave arc and the convex arc are alternatively arranged.

3. The bulk acoustic resonator according to claim 2, wherein the arcs comprise a first arc and a second arc that are sequentially connected end to end, the first arc is a convex arc, and the second arc is a concave arc.

4. The bulk acoustic resonator according to claim 2, wherein the arcs comprise a first arc, a second arc, a third arc and a fourth arc that are sequentially connected end to end, the first arc and the third arc are convex arcs and are symmetrically arranged with respect to a first direction, the second arc and the fourth arc are concave arcs and are symmetrically arranged with respect to a second direction, and the first direction is perpendicular to the second direction.

5. The bulk acoustic resonator according to claim 2, wherein the arcs comprise a first arc, a second arc, a third arc, a fourth arc, a fifth arc, a sixth arc, a seventh arc and an eighth arc that are sequentially connected end to end, the first arc, the third arc, the fifth arc and the seventh arc are convex arcs, and the second arc, the fourth arc, the sixth arc and the eighth arc are concave arcs.

6. The bulk acoustic resonator according to claim 1, wherein the piezoelectric layer is made of any one of aluminum nitride, lithium niobate, lithium tantalate, lead zirconate titanate and scandium-doped aluminum nitride.

7. The bulk acoustic resonator according to claim 1, wherein the bottom electrode is made of any one of molybdenum, aluminum, platinum, silver, tungsten and gold.

8. The bulk acoustic resonator according to claim 1, wherein the top electrode is made of any one of molybdenum, aluminum, platinum, silver, tungsten and gold.

9. The bulk acoustic resonator according to claim 1, wherein in the resonance area, an outline shape of the orthographic projection of the piezoelectric layer on the substrate is a closed figure formed by connecting M arcs end to end, and the closed figure is an axisymmetric figure, wherein M is an integer greater than or equal to 2, and the arcs comprise a concave arc that is concave toward the center of the resonance area and a convex arc that is convex away from the center of the resonance area.

10. A method for manufacturing a bulk acoustic resonator, comprising: providing a substrate having a cavity, sequentially forming a bottom electrode, a piezoelectric layer and a top electrode on the substrate, and forming a resonance area by an overlapping area of orthographic projections of the bottom electrode, the piezoelectric layer and the top electrode on the substrate,
wherein in the resonance area, an outline shape of the orthographic projection of each of the bottom electrode and the top electrode on the substrate is a closed figure formed by connecting M arcs end to end, and the closed figure is an axisymmetric figure, wherein M is an integer greater than or equal to 2, and the arcs comprise a concave arc that is concave toward a center of the resonance area and a convex arc that is convex away from the center of the resonance area.

11. The method for manufacturing a resonator according to claim 10, wherein
the bottom electrode is etched into a closed figure having an outline shape formed by connecting M arcs end to end through photolithography and an ion etching technology, and the closed figure is an axisymmetric figure.

12. The method for manufacturing a resonator according to claim 11, wherein the piezoelectric layer is made of any one of aluminum nitride, lithium niobate, lithium tantalate, lead zirconate titanate and scandium-doped aluminum nitride.

13. The method for manufacturing a resonator according to claim 12, wherein shapes of the orthographic projections of the top electrode and the bottom electrode on the substrate coincide, or an area of the orthographic projection of the top electrode on the substrate is greater than that of the orthographic projection of the bottom electrode on the substrate, or an area of the orthographic projection of the top electrode on the substrate is smaller than that of the orthographic projection of the bottom electrode on the substrate.

14. The method for manufacturing a resonator according to claim 13, wherein the substrate is etched to form a first cavity, and an outline shape of an orthographic projection of the first cavity on the substrate is the same as that of the orthographic projection of the top electrode on the substrate.

15. The method for manufacturing a resonator according to claim 11, wherein the substrate is etched to form a second cavity, a sacrificial layer is deposited in the second cavity, a release hole is etched through the photolithography and an ion etching technology, and etching gas or liquid is introduced to remove the sacrificial layer.

16. The method for manufacturing a resonator according to claim 15, wherein a seed layer grows on the sacrificial layer, further the piezoelectric layer grows on the seed layer, and the seed layer provides a lattice matching interface required for growth of the piezoelectric layer.

17. The method for manufacturing a resonator according to claim 16, wherein shapes of the orthographic projections of the top electrode and the bottom electrode on the substrate coincide, or an area of the orthographic projection of the top electrode on the substrate is greater than that of the orthographic projection of the bottom electrode on the substrate, or an area of the orthographic projection of the top electrode on the substrate is smaller than that of the orthographic projection of the bottom electrode on the substrate.

18. The method for manufacturing a resonator according to claim 17, wherein an outline shape of an orthographic projection of the second cavity on the substrate is the same as that of the orthographic projection of the top electrode on the substrate.

19. A filter, comprising a bulk acoustic resonator, wherein the bulk acoustic resonator comprises a substrate having a cavity, and a bottom electrode, a piezoelectric layer and a top electrode that are sequentially arranged on the substrate, wherein an overlapping area of orthographic projections of the bottom electrode, the piezoelectric layer and the top electrode on the substrate forms a resonance area; and
in the resonance area, an outline shape of the orthographic projection of each of the bottom electrode and the top electrode on the substrate is a closed figure formed by connecting M arcs end to end, and the closed figure is an axisymmetric figure, wherein M is an integer greater than or equal to 2, and the arcs comprise a concave arc that is concave toward a center of the resonance area and a convex arc that is convex away from the center of the resonance area.

20. The filter according to claim 19, wherein the concave arc and the convex arc are alternatively arranged.
